(19) United States
(12) Patent Application Publication
(10) Pub. No.: US 2026/0136586 A1
(43) Pub. Date: May 14, 2026

(54) SEMICONDUCTOR DEVICE AND METHOD OF MANUFACTURING THE SAME

(71) Applicant: Renesas Electronics Corporation, Tokyo (JP)

(72) Inventor: Yukio MAKI, Tokyo (JP)

(21) Appl. No.: 19/317,937

(22) Filed: Sep. 3, 2025

(30) Foreign Application Priority Data
Nov. 12, 2024 (JP) 2024-197308

(51) Int. Cl. H10D 30/63; H01L 21/306; H01L 21/308; H10D 30/01; H10D 64/00; H10D 64/23; H10D 64/27; H10D 64/62

(52) U.S. Cl. CPC H10D 30/63; H10D 30/025; H10D 64/112; H10D 64/117; H10D 64/2527; H10D 64/513; H10D 64/518; H10D 64/62; H10P 50/642; H10P 50/691

(57) ABSTRACT

A gate electrode is formed in a trench. An insulating film is formed on the gate electrode so as to protrude from an upper surface of a semiconductor substrate. A sidewall spacer is formed on a side surface of the insulating film and on the upper surface of the semiconductor substrate. A hole is formed in a portion of the semiconductor substrate exposed from the insulating film and the sidewall spacer. A barrier metal film is formed in the hole. A second opening width of the hole at a second position, corresponding to a position of a junction surface between a body region and a source region, is larger than a first opening width of the hole at a first position, corresponding to a position of the upper surface of the semiconductor substrate. The barrier metal film includes a silicide film and a metal film.

### CROSS-REFERENCE TO RELATED APPLICATIONS

The application claims priority from Japanese Patent Application No. 2024-197308, filed on Nov. 12, 2024, the entire contents of which are hereby incorporated by reference.

### BACKGROUND

The present invention relates to a semiconductor device and a method of manufacturing the same, specifically to a method of manufacturing a semiconductor device equipped with a gate electrode in a trench.

In semiconductor devices equipped with semiconductor elements such as power MOSFETs (Metal Oxide Semiconductor Field Effect Transistors), a trench gate structure is applied where a gate electrode is formed in the trench. In the semiconductor substrate located at the side surface of the trench, a body region is formed, and in the body region, a source region is formed. A portion of the body region adjacent to the gate electrode via a gate insulating film functions as a channel region.

Generally, to electrically connect the body region and the source region to the source electrode, a hole is formed that penetrates through the source region and reaches the body region.

There are disclosed techniques listed below.
[Patent Document 1] Japanese Unexamined Patent Application Publication No. 2002-246596
[Patent Document 2] Japanese Unexamined Patent Application Publication No. 2024-128687

For example, Patent Document 1 discloses a technique for forming holes in a self-aligned manner. First, a cap film made of an insulating film is formed in the trench and on the gate electrode. Next, by performing an etching treatment using the cap film as a mask, the upper surface of the semiconductor substrate is recessed. As a result, the cap film protrudes from the upper surface of the semiconductor substrate. Then, a body region is formed in the semiconductor substrate exposed from the cap film, and a source region is formed in the body region. Next, a sidewall spacer is formed on the side surface of the cap film. Subsequently, by performing an etching treatment using the cap film and the sidewall spacer as a mask, a hole is formed in the semiconductor substrate. Then, a high concentration contact region is formed in the semiconductor substrate near the bottom portion of the hole. Finally, a source electrode is formed on the cap film and the sidewall spacer to fill the hole.

As shown in Patent Document 2, a technique is also known in which a plug is formed in the hole, and then a source electrode is formed to be electrically connected to the plug. The plug is formed of a laminated film including a barrier metal film and a main conductive film.

In Patent Document 2, a laminated film including a metal film and a nitride metal film is used as the barrier metal film. The metal film is a titanium film, and the nitride metal film is a titanium nitride film. First, the metal film is formed in the hole. Next, the nitride metal film is formed on the metal film. Then, by reacting to the metal film with the silicon contained in the semiconductor substrate through heat treatment, a silicide film is formed. Subsequently, a tungsten film is formed to fill the hole via such a barrier metal film.

### SUMMARY

In recent years, with the miniaturization of semiconductor devices, it is required to reduce the opening width of the hole. Therefore, when a silicide film is formed at the side portion of the hole, it tends to be formed near the channel region. Additionally, during the formation of the silicide film, there is a problem of aggregation occurring in the silicide film, and stress from the silicide film may cause cracks in the nitride metal film. These issues can reduce the reliability of the semiconductor device.

Other problems and novel features will become apparent from the description of this specification and the accompanying drawings.

A brief overview of the typical embodiments disclosed in the present application is as follows.

In one embodiment, a semiconductor device includes a semiconductor substrate of a first conductivity type having an upper surface, a trench formed in the semiconductor substrate, a gate electrode formed in the trench, an insulating film formed on the gate electrode to protrude from the upper surface of the semiconductor substrate, a body region of a second conductivity type opposite to the first conductivity type formed in the semiconductor substrate, a source region of the first conductivity type formed in the body region, a sidewall spacer formed on the side surface of the insulating film and on the upper surface of the semiconductor substrate, a hole formed in a portion of the semiconductor substrate exposed from the insulating film and the sidewall spacer to penetrate through the source region and reach the body region, and a barrier metal film formed in the hole. The opening width of the hole at a second position corresponding to a position of the junction surface between the body region and the source region is larger than the opening width of the hole at a first position corresponding to a position of the upper surface of the semiconductor substrate. The barrier metal film includes a silicide film formed in the hole and a second metal film formed on the silicide film.

In one embodiment, a method of manufacturing a semiconductor device includes: (a) preparing a semiconductor substrate of a first conductivity type having an upper surface; (b) forming a trench in the semiconductor substrate; (c) forming a gate electrode in the trench; (d) forming an insulating film in the trench and on the gate electrode; (e) performing an etching treatment on the semiconductor substrate using the insulating film as a mask to lower the position of the upper surface of the semiconductor substrate below the position of the upper surface of the insulating film; (f) forming a body region of a second conductivity type opposite to the first conductivity type in the portion of the semiconductor substrate exposed from the insulating film; (g) forming a source region of the first conductivity type in the body region; (h) forming a sidewall spacer on the side surface of the insulating film and on the upper surface of the semiconductor substrate; (i) performing an etching treatment on the semiconductor substrate using the insulating film and the sidewall spacer as a mask to form a hole that penetrates through the source region and reaches the body region; and (j) forming a barrier metal film in the hole. Before (j), the opening width of the hole at a second position corresponding to a position of the junction surface of the body region and the source region is larger than the opening width of the hole at a first position corresponding to a position of the upper surface of the semiconductor substrate. (j) includes: (j1) forming a first metal film in the hole using a sputtering method; (j2) forming a second metal film on the first metal film using a sputtering method; and (j3) performing heat treatment to react the first metal film with the silicon contained in the semiconductor substrate to form a silicide film.

According to one embodiment, the reliability of the semiconductor device can be improved.

### BRIEF DESCRIPTION OF THE DRAWINGS

FIG. 1 is a plan view showing a semiconductor device in a first embodiment.

FIG. 2 is a cross-sectional view showing a main portion of the semiconductor device in the first embodiment.

FIG. 3 is a cross-sectional view showing a manufacturing step of the semiconductor device in the first embodiment.

FIG. 4 is a cross-sectional view showing the subsequent manufacturing step following FIG. 3.

FIG. 5 is a cross-sectional view showing the subsequent manufacturing step following FIG. 4.

FIG. 6 is a cross-sectional view showing the subsequent manufacturing step following FIG. 5.

FIG. 7 is a cross-sectional view showing the subsequent manufacturing step following FIG. 6.

FIG. 8 is a cross-sectional view showing the subsequent manufacturing step following FIG. 7.

FIG. 9 is a cross-sectional view showing the subsequent manufacturing step following FIG. 8.

FIG. 10 is a cross-sectional view showing the subsequent manufacturing step following FIG. 9.

FIG. 11 is a cross-sectional view showing the subsequent manufacturing step following FIG. 10.

FIG. 12 is a cross-sectional view showing the subsequent manufacturing step following FIG. 11.

FIG. 13 is a cross-sectional view showing the subsequent manufacturing step following FIG. 12.

FIG. 14 is a cross-sectional view showing the subsequent manufacturing step following FIG. 13.

FIG. 15 is a cross-sectional view showing the hole before forming the barrier metal film in the first embodiment.

FIG. 16 is a cross-sectional view showing the hole immediately after forming two metal films as the barrier metal film in the first embodiment.

FIG. 17 is cross-sectional view showing the hole immediately after forming the silicide film in the first embodiment.

FIG. 18 is a cross-sectional view showing the hole after forming the barrier metal film in the first embodiment.

FIG. 19 is a cross-sectional view showing the hole immediately after forming an additional metal film as the barrier metal film in the first embodiment.

FIG. 20 is a cross-sectional view showing the hole after forming the barrier metal film in the first embodiment.

FIG. 21 is a cross-sectional view showing the hole after forming the plug in the first embodiment.

FIG. 22 is a cross-sectional view showing the hole before forming the barrier metal film in an examined example.

FIG. 23 is a cross-sectional view showing the hole immediately after forming two metal films as the barrier metal film in the examined example.

FIG. 24 is a cross-sectional view showing the hole immediately after forming the silicide film in the examined example.

FIG. 25 is a cross-sectional view showing the hole after forming the plug in the examined example.

### DETAILED DESCRIPTION

Hereinafter, the embodiments will be described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In this application, the X direction, Y direction, and Z direction described intersect and are orthogonal to each other. The expressions such as “plan view” or “in plan view” used in this application mean a plane constituted by the X and Y directions, and viewing this “plane” from the Z direction.

### First Embodiment

### Structure of Semiconductor Device

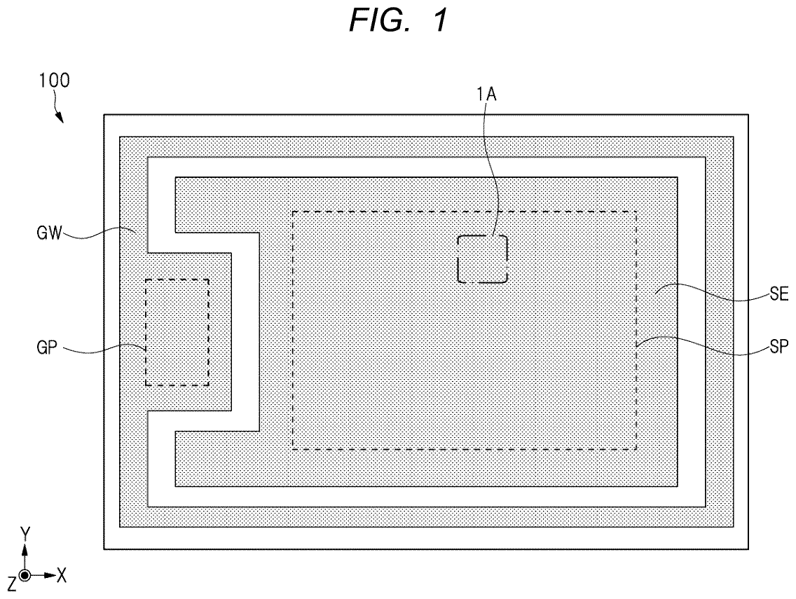

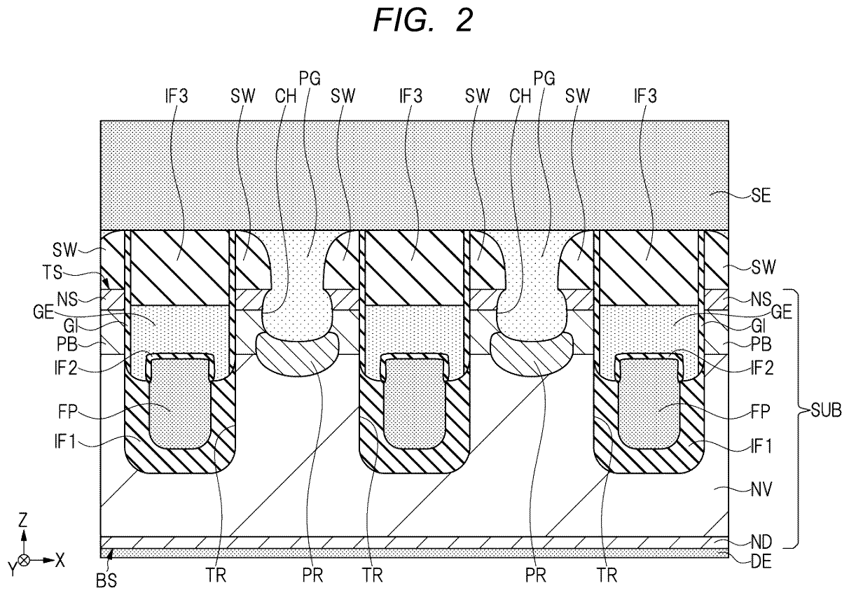

A semiconductor device 100 in the first embodiment will be described below with reference to FIGS. 1 and 2. The semiconductor device 100 includes a MOSFET with a trench gate structure as a semiconductor element. The MOSFET of the first embodiment has a split gate structure with a gate electrode GE and a field plate electrode FP.

The main features of the first embodiment lie in the structure and manufacturing method of each of the hole CH and the barrier metal film BM formed in the hole CH, which will be described in detail later.

FIG. 1 is a plan view of a semiconductor chip, which is the semiconductor device 100. FIG. 2 shows the cross-sectional structure of a region 1A shown in FIG. 1.

FIG. 1 mainly shows the wiring pattern formed over the semiconductor substrate SUB. Most of the semiconductor device 100 is covered with a source electrode SE. In plan view, a gate wiring GW surrounds the source electrode SE.

Although not shown here, the source electrode SE and the gate wiring GW are covered with a protective film such as a polyimide film. An opening is formed in a part of the protective film. The portion of the source electrode SE exposed at the opening functions as a source pad SP. Also, the portion of the gate wiring GW exposed at the opening functions as a gate pad GP. By connecting external connection members to the source pad SP and the gate pad GP, the semiconductor device 100 is electrically connected to other semiconductor chips, lead frames, or wiring boards. The external connection member is, for example, a wire made of aluminum, gold, or copper, or a clip made of a copper plate.

As shown in FIG. 2, the semiconductor device 100 includes an n-type semiconductor substrate SUB having an upper surface TS and a lower surface BS. The semiconductor substrate SUB is made of n-type silicon. The semiconductor substrate SUB may be a laminate of an n-type silicon substrate ND and an n-type silicon layer NV formed on the n-type silicon substrate ND. An impurity concentration of the n-type silicon substrate ND is higher than an impurity concentration of the n-type silicon layer NV.

A drain electrode DE is formed on the lower surface BS of the semiconductor substrate SUB. The drain electrode DE is made of, for example, a single layer metal film such as an aluminum film, titanium film, nickel film, gold film, or silver film, or a laminated film obtained by appropriately laminating these metal films. A drain potential is supplied to the semiconductor substrate SUB (silicon substrate ND, silicon layer NV) from the drain electrode DE.

A plurality of trenches TR are formed in the semiconductor substrate SUB so as to reach a predetermined depth from the upper surface TS of the semiconductor substrate SUB. Each of the plurality of trenches TR extends in the Y direction. In each of the plurality of trenches TR, a field plate electrode FP is formed via an insulating film IF1.

In each of the plurality of trenches TR, a gate insulating film GI is formed on the insulating film IF1. The insulating film IF2 is formed to cover the field plate electrode FP exposed from the insulating film IF1. A gate electrode GE is formed on the field plate electrode FP via the insulating film IF2. The field plate electrode FP and the gate electrode GE are each a polycrystalline silicon film into which n-type impurities are introduced.

The insulating film IF1 is formed between the semiconductor substrate SUB and the field plate electrode FP. The insulating film IF2 is formed between the gate electrode GE and the field plate electrode FP. The gate insulating film GI is formed between the semiconductor substrate SUB and the gate electrode GE. The semiconductor substrate SUB, the gate electrode GE, and the field plate electrode FP are electrically insulated from each other by the insulating film IF1, the insulating film IF2, and the gate insulating film GI. The insulating film IF1, the insulating film IF2, and the gate insulating film GI are, for example, silicon oxide films.

An insulating film IF3 is formed on the gate electrode GE. The insulating film IF3 protrudes from the upper surface TS of the semiconductor substrate SUB. In other words, the position of the upper surface of the insulating film IF3 is higher than the position of the upper surface TS of the semiconductor substrate SUB. The insulating film IF3 is, for example, a silicon oxide film (HDP film).

In the portion of the semiconductor substrate SUB exposed from the insulating film IF3, a p-type body region PB is formed. The depth of the body region PB from the upper surface TS of the semiconductor substrate SUB is shallower than the depth of the trench TR from the upper surface TS of the semiconductor substrate SUB. An n-type source region NS is formed in the body region PB. The source region NS has a higher impurity concentration than the silicon layer NV.

A sidewall spacer SW is formed on the side surface of the insulating film IF3 and on the upper surface TS of the semiconductor substrate SUB. The sidewall spacer SW is, for example, a silicon oxide film (TEOS film). In the portion of the semiconductor substrate SUB exposed from the insulating film IF3 and the sidewall spacer SW, a hole CH is formed. The hole CH penetrates through the source region NS and reaches the body region PB.

In the body region PB located around the hole CH, a p-type contact region PR is formed. The contact region PR is located under the source region NS and is separated from the source region NS. An impurity concentration of the contact region PR is higher than an impurity concentration of the body region PB.

A plug PG is formed in the hole CH. The plug PG is located at an upper portion of the hole CH and is also formed in the space adjacent to the sidewall spacer SW. As will be described in detail later, the plug PG includes a barrier metal film BM and a metal film MF4. The barrier metal film BM includes a silicide film SI formed in the hole CH and a metal film MF2 formed on the silicide film SI. The barrier metal film BM may further include a metal film MF3. The silicide film SI is formed between the metal film MF2 and the semiconductor substrate SUB.

A source electrode SE is formed on the insulating film IF3 and the sidewall spacer SW. The source electrode SE is electrically connected to the source region NS, the body region PB, and the contact region PR via the plug PG, and supplies a source potential to these impurity regions.

Although not shown, a gate electrode GE, an insulating film IF3, and an interlayer insulating film are located below the gate wiring GW. Another hole is formed in the insulating film IF3, and a plug PG is formed in the hole. The gate wiring GW is electrically connected to the gate electrode GE via the plug PG and supplies a gate potential to the gate electrode GE.

Although not shown, in some of the trenches TR, the gate electrode GE is not formed in the trench TR, and the field plate electrode FP and the insulating film IF3 are formed in the trench TR. Another hole is formed in the insulating film IF3, and a plug PG is formed in the hole. The source electrode SE is electrically connected to the field plate electrode FP via the plug PG and supplies a source potential to the field plate electrode FP.

The source electrode SE and the gate wiring GW may be formed of, for example, a barrier metal film and a conductive film formed on the barrier metal film. The barrier metal film is, for example, a titanium tungsten film. The conductive film is, for example, an aluminum alloy film to which copper or silicon is added.

### Manufacturing Method of Semiconductor Device

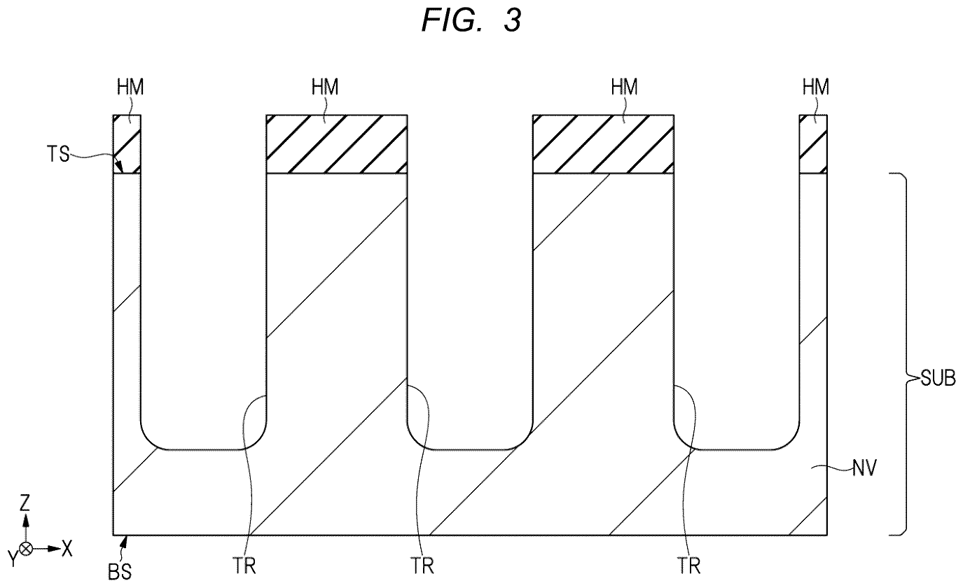

Each manufacturing step included in a manufacturing method of the semiconductor device 100 will be described below using FIGS. 3 to 14.

As shown in FIG. 3, first, an n-type semiconductor substrate SUB having an upper surface TS and a lower surface BS is prepared. As described above, the semiconductor substrate SUB may be a laminate of an n-type silicon substrate ND and an n-type silicon layer NV formed on the n-type silicon substrate ND using an epitaxial growth method.

Next, on the semiconductor substrate SUB, for example, a silicon oxide film is formed using a CVD (Chemical Vapor Deposition) method. Then, by patterning the silicon oxide film using photolithography technique and anisotropic etching treatment, a hard mask HM is formed. Subsequently, using the hard mask HM as a mask, anisotropic etching treatment is performed to form a trench TR in the semiconductor substrate SUB, reaching a predetermined depth from the upper surface TS. Thereafter, the hard mask HM is removed by isotropic etching treatment using a solution containing hydrofluoric acid, for example.

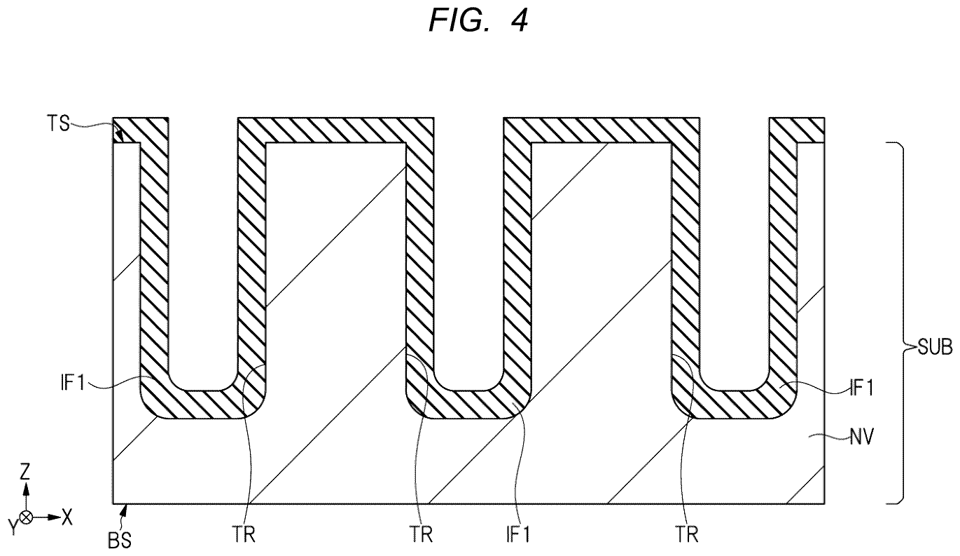

As shown in FIG. 4, for example, by thermal oxidation, an insulating film IF1 is formed in the trench TR and on the upper surface TS of the semiconductor substrate SUB.

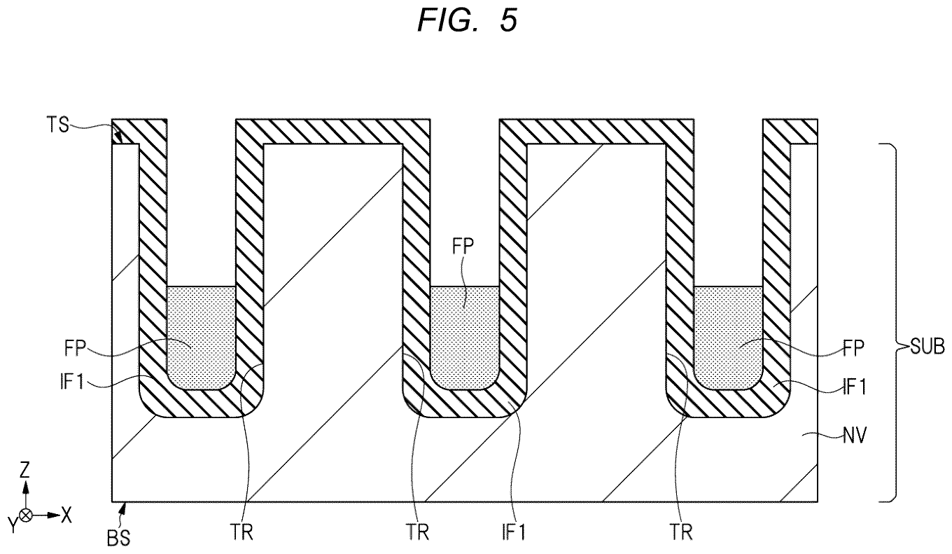

As shown in FIG. 5, first, a conductive film is formed on the insulating film IF1 using, for example, a CVD method. The conductive film is, for example, an n-type polycrystalline silicon film. Next, by performing polishing treatment using a CMP (Chemical Mechanical Polishing) method or anisotropic etching treatment, the conductive film located outside the trench TR is removed. Then, by further performing anisotropic etching treatment, the upper surface of the conductive film located in the trench TR is recessed, forming a field plate electrode FP in the trench TR.

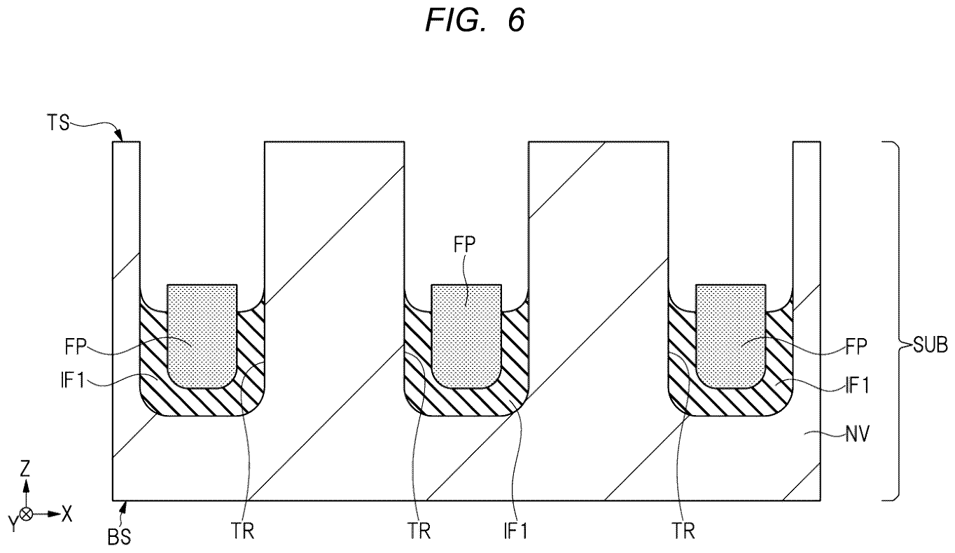

As shown in FIG. 6, by isotropic etching treatment, the insulating film IF1 located on the upper surface TS of the semiconductor substrate SUB is removed, and the position of the upper surface of the insulating film IF1 located in the trench TR is recessed so that the position of the upper surface of the insulating film IF1 located in the trench TR is lower than the position of the upper surface of the field plate electrode FP.

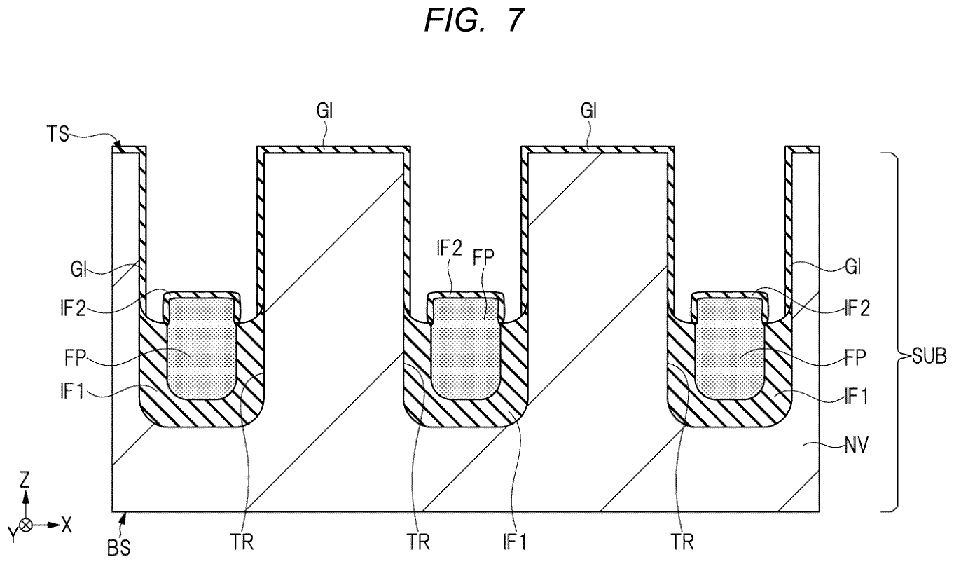

As shown in FIG. 7, by thermal oxidation treatment, a gate insulating film GI is formed on the upper surface TS of the semiconductor substrate SUB and in an upper portion of the trench TR located on the insulating film IF1, and an insulating film IF2 is formed to cover the field plate electrode FP exposed from the insulating film IF1.

The method of forming the insulating film IF2 may be as follows. Using, for example, a plasma CVD method, an insulating film (HDP film) is formed on the field plate electrode FP and film IF1 to fill the trench TR. Next, by the insulating performing polishing treatment using a CMP method or anisotropic etching treatment, the insulating film located outside the trench TR is removed. Thereafter, by reducing the thickness of the insulating film through wet etching treatment or the like, the insulating film IF2 may be formed.

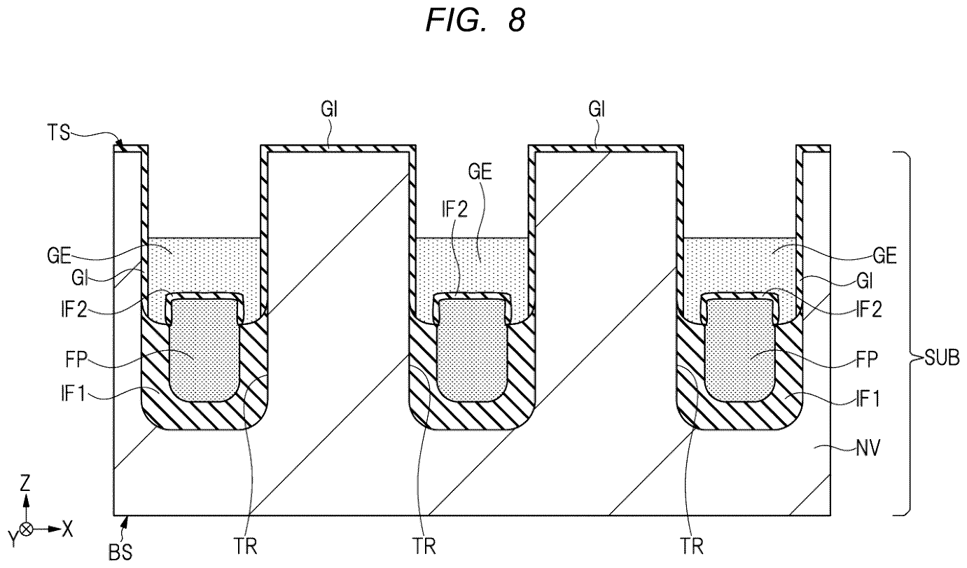

As shown in FIG. 8, first, using, for example, a CVD method, a conductive film is formed on the gate insulating film GI, on the insulating film IF2, and on the insulating film IF1 to fill the trench TR. The conductive film is, for example, an n-type polycrystalline silicon film.

Next, by performing anisotropic etching treatment on the conductive film, the conductive film located outside the trench TR is removed, and the upper surface of the conductive film located in the trench TR is recessed. In this way, a gate electrode GE is formed in the trench TR. At this point, the position of the upper surface of the gate electrode GE is lower than the position of the upper surface TS of the semiconductor substrate SUB.

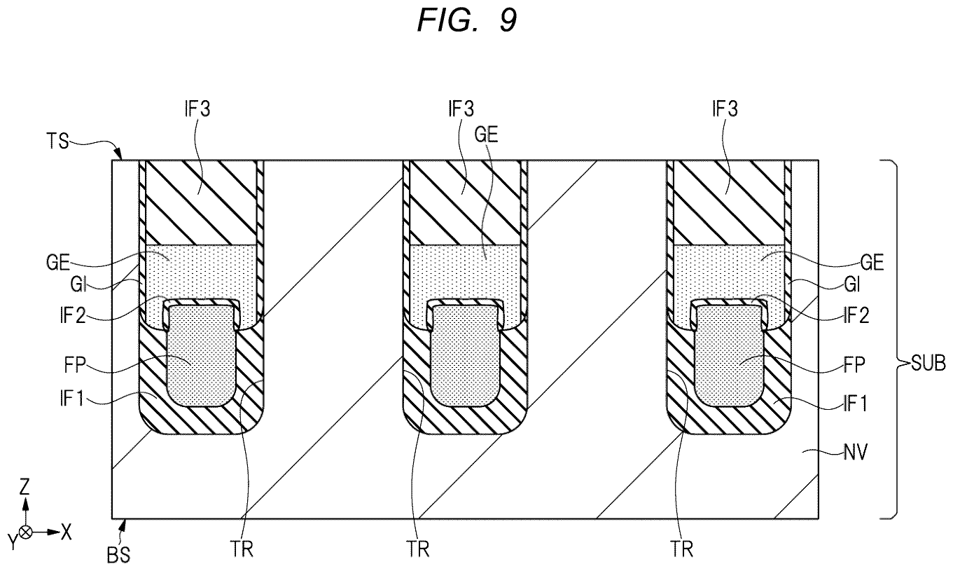

As shown in FIG. 9, first, using, for example, a plasma CVD method, an insulating film (HDP film) IF3 is formed on the gate electrode GE and the gate insulating film GI to fill the trench TR. Next, by performing polishing treatment using a CMP method or anisotropic etching treatment, the insulating film IF3 located outside the trench TR is removed. At this time, the gate insulating film GI formed outside the trench TR is also removed. In this way, the insulating film IF3 is formed on the gate electrode GE and in the trench TR.

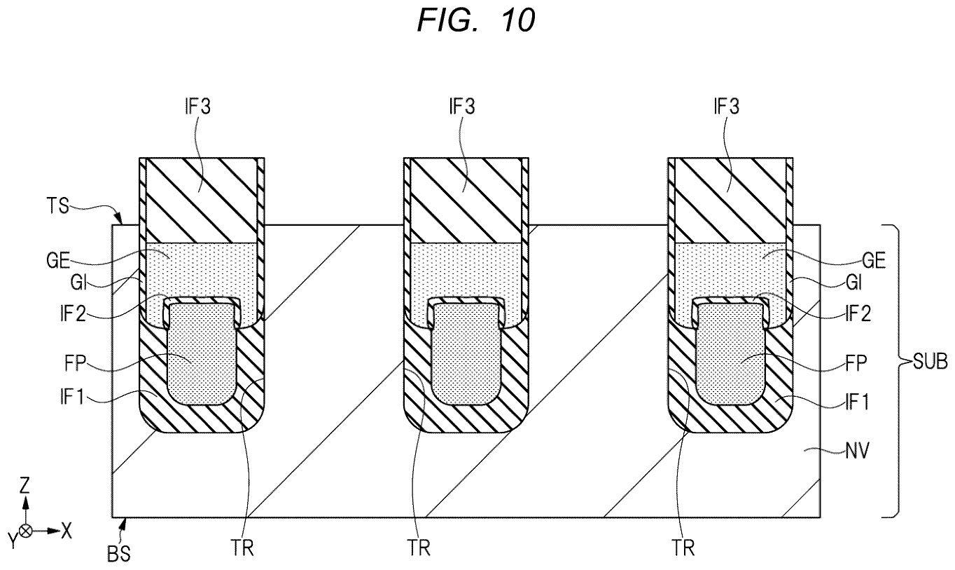

As shown in FIG. 10, by performing anisotropic etching treatment on the semiconductor substrate SUB using the insulating film IF3 as a mask, the position of the upper surface TS of the semiconductor substrate SUB is made lower than the position of the upper surface of the insulating film IF3. In other words, the insulating film IF3 is made to protrude from the upper surface TS of the semiconductor substrate SUB.

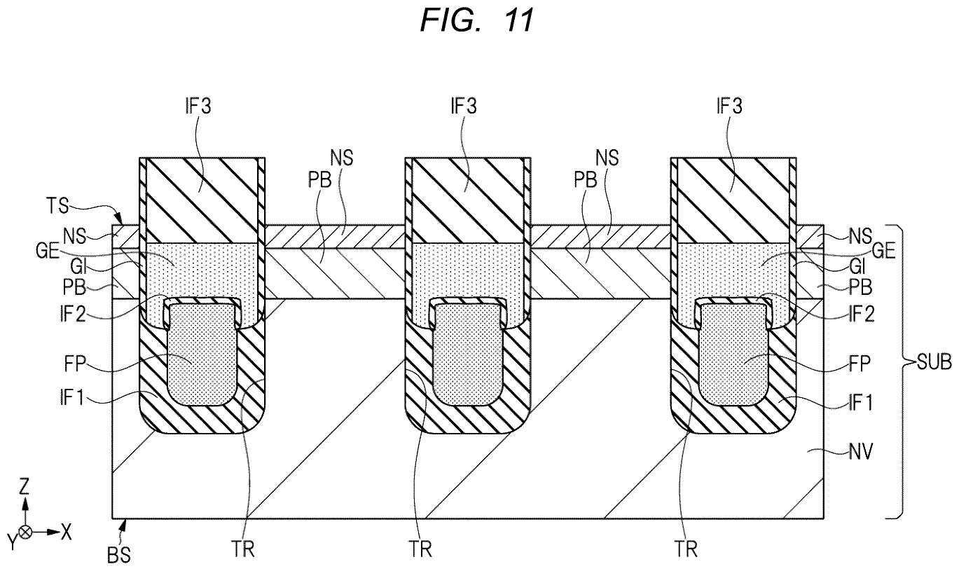

As shown in FIG. 11, first, using photolithography technique and ion implantation method, a p-type body region PB is formed in a portion of the semiconductor substrate SUB exposed from the insulating film IF3. The body region PB is formed so that a depth of the body region PB from the upper surface TS of the semiconductor substrate SUB is shallower than the depth of the trench TR. Next, using photolithography technique and ion implantation method, an n-type source region NS is formed in the body region PB.

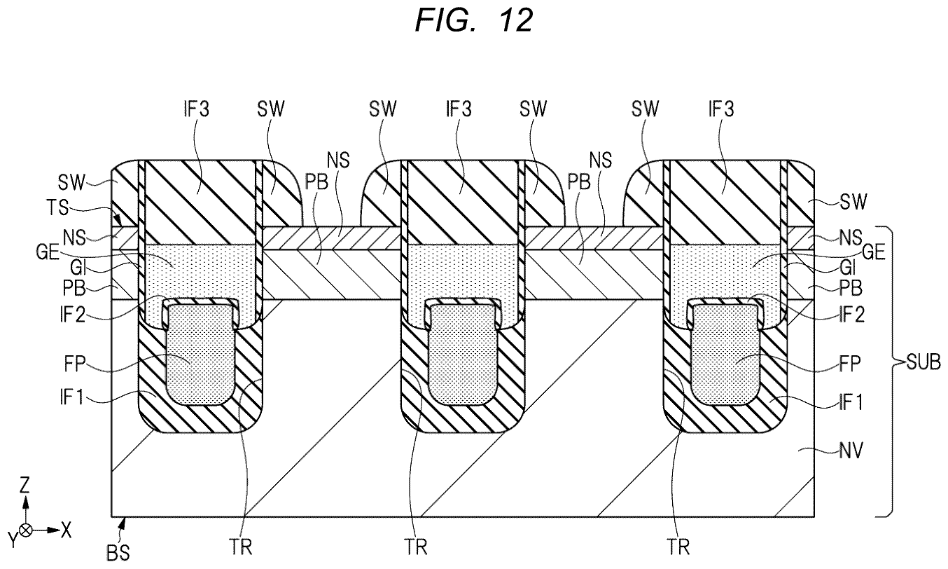

As shown in FIG. 12, first, using, for example, a CVD method, an insulating film is formed on the upper surface TS of the semiconductor substrate SUB to cover the insulating film IF3. The insulating film is, for example, a silicon oxide film. Next, by performing anisotropic etching treatment on the insulating film, the insulating film is left on the side surface of the insulating film IF3 and the upper surface TS of the semiconductor substrate SUB. In this way, a sidewall spacer SW is formed on the side surface of the insulating film IF3 and on the upper surface TS of the semiconductor substrate SUB.

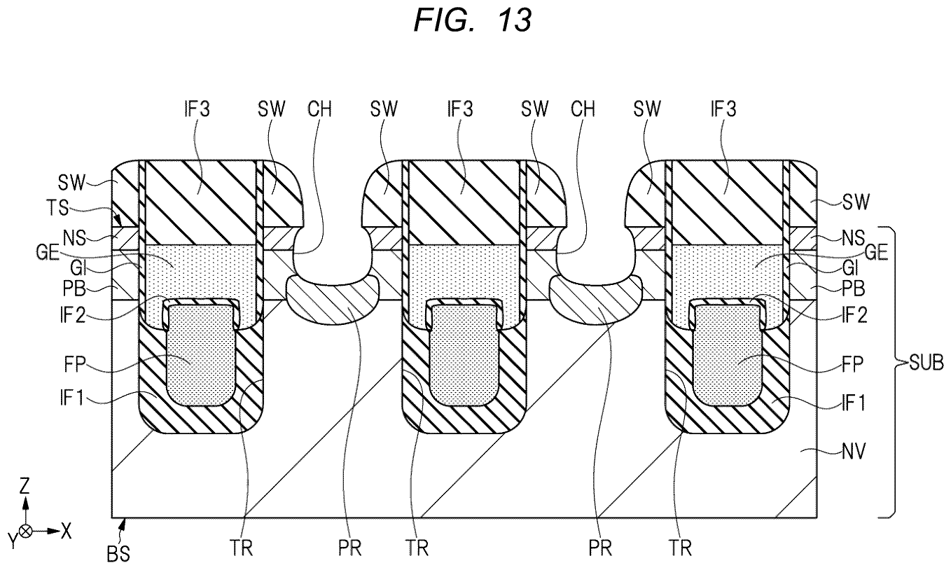

As shown in FIG. 13, first, by performing etching treatment on the semiconductor substrate SUB using the insulating film IF3 and the sidewall spacer SW as masks, a hole CH is formed that penetrates through the source region NS and reaches the body region PB. This etching treatment includes anisotropic etching treatment and isotropic etching treatment, which will be described in detail later. Next, using ion implantation method, a p-type contact region PR is formed in the body region PB located around the hole CH.

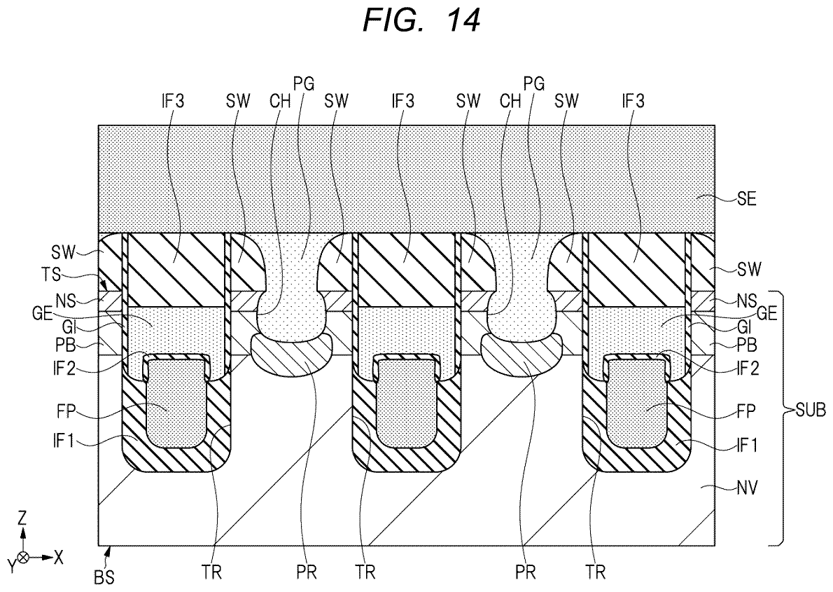

As shown in FIG. 14, first, a plug PG is formed in the hole CH. The plug PG is also formed in the space adjacent to the sidewall spacer SW, located at the upper portion of the hole CH. The detailed manufacturing step of the plug PG will be described later.

Next, using a sputtering method, a conductive film is formed on the plug PG. The conductive film is, for example, an aluminum alloy film with added copper or silicon. Next, by patterning the conductive film, a source electrode SE and a gate wiring GW are formed.

Thereafter, through the following manufacturing steps, the structure shown in FIG. 2 is obtained.

First, using, for example, a coating method, a protective film made of, for example, a polyimide film is formed on the source electrode SE and the gate wiring GW. Next, by forming openings in a part of the protective film, the portions of the source electrode SE and the gate wiring GW that become the source pad SP and the gate pad GP are exposed. Next, if necessary, the lower surface BS of the semiconductor substrate SUB is polished. Next, using a sputtering method, a drain electrode DE is formed on the lower surface BS of the semiconductor substrate SUB.

### Main Features of First Embodiment

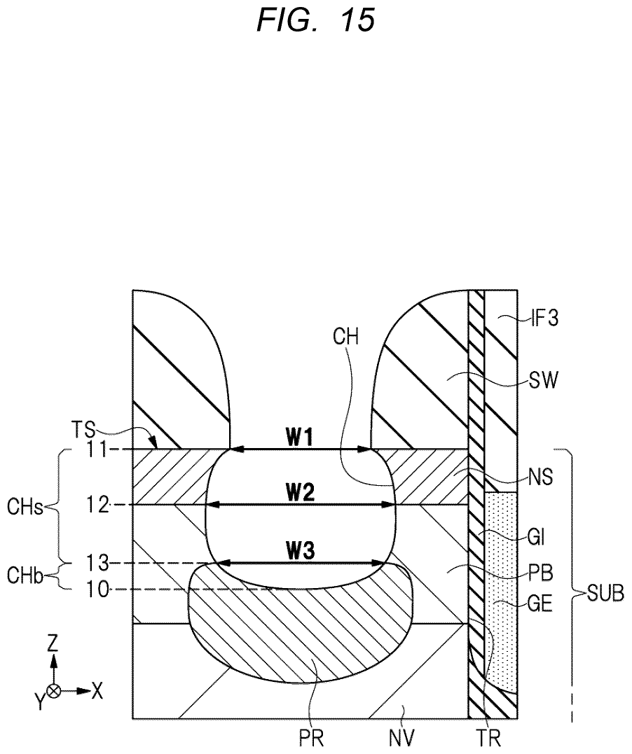

The structure of the hole CH and the structure of the barrier metal film BM in the first embodiment, as well as the manufacturing method of the hole CH and the barrier metal film BM, will be described in detail below using FIGS. 15 to 21. FIG. 15 is an enlarged cross-sectional view around the hole CH, showing the state before forming the barrier metal film BM.

As shown in FIG. 15, the first position 11 corresponds to the position of the upper surface TS of the semiconductor substrate SUB. The second position 12 corresponds to the position of the junction surface between the body region PB and the source region NS. The third position 13 corresponds to a position 10 to 30 nm over the deepest part of the hole CH.

In the first embodiment, the hole CH has a bowing shape. In other words, the opening width W3 of the hole CH at the third position 13 is smaller than the opening width W2 of the hole CH at the second position 12, and larger than the opening width W1 of the hole CH at the first position 11.

In the following description, a portion of the hole CH extending from the first position 11 to the third position 13 is referred to as a side portion CHs of the hole CH, and a portion extending from the third position 13 to the deepest part 10 of the hole CH is referred to as a bottom portion CHb of the hole CH. That is, the inner wall surface of the hole CH is configured by the side portion CHs and the bottom portion CHb.

To form such a hole CH, as described in FIG. 13, an etching treatment is performed on the semiconductor substrate SUB using the insulating film IF3 and the sidewall spacer SW as masks. This etching treatment includes at least an anisotropic etching treatment and may also include an isotropic etching treatment.

In the anisotropic etching treatment, Cl₂ gas and O₂ gas are used. The value of “flow rate of Cl₂ gas/flow rate of O₂ gas” is, for example, 6 or more and 13 or less. Specifically, the flow rate of Cl₂ gas is 60 sccm or more and 80 sccm or less, and the flow rate of O₂ gas is 6 sccm or more and 10 sccm or less. By performing such an anisotropic etching treatment, it becomes easier to make the opening width W2 larger than the opening width W1.

In the isotropic etching treatment, buffered hydrofluoric acid is used. Buffered hydrofluoric acid is a solution containing hydrofluoric acid (HF), ammonium fluoride (NH4F), and water. In this isotropic etching treatment, both silicon and silicon oxide are etched. At the interface between the upper surface TS of the semiconductor substrate SUB and the sidewall spacer SW, the etching rate becomes slower compared to the exposed portions of the semiconductor substrate SUB. Therefore, it becomes easier to make the opening width W3 larger than the opening width W1.

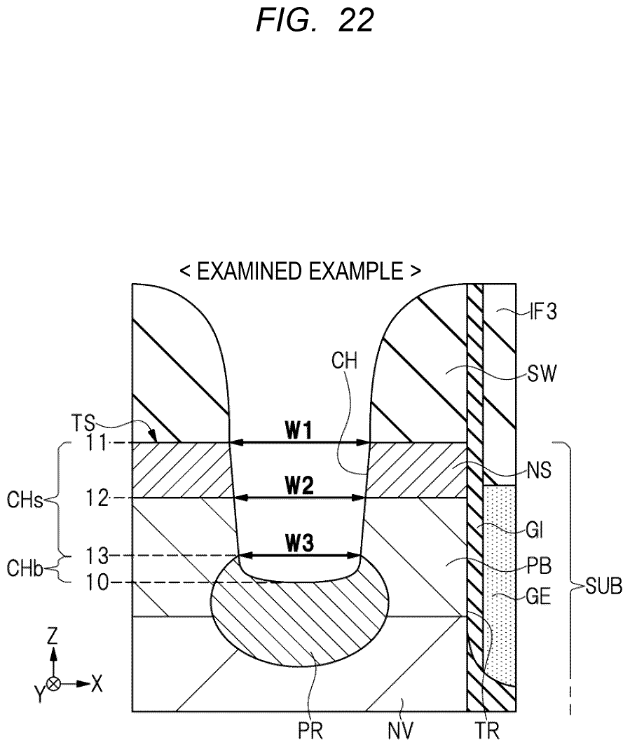

The reason for forming the hole CH in such a shape in the first embodiment will be explained below using the examined examples shown in FIGS. 22 to 25.

As shown in FIG. 22, in the examined example, unlike the first embodiment, the opening width W1 of the hole CH at the first position 11 is larger than the opening width W2 of the hole CH at the second position 12, and the opening width W2 of the hole CH at the second position 12 is larger than the opening width W3 of the hole CH at the third position 13. In this state, a barrier metal film BM is formed in the hole CH.

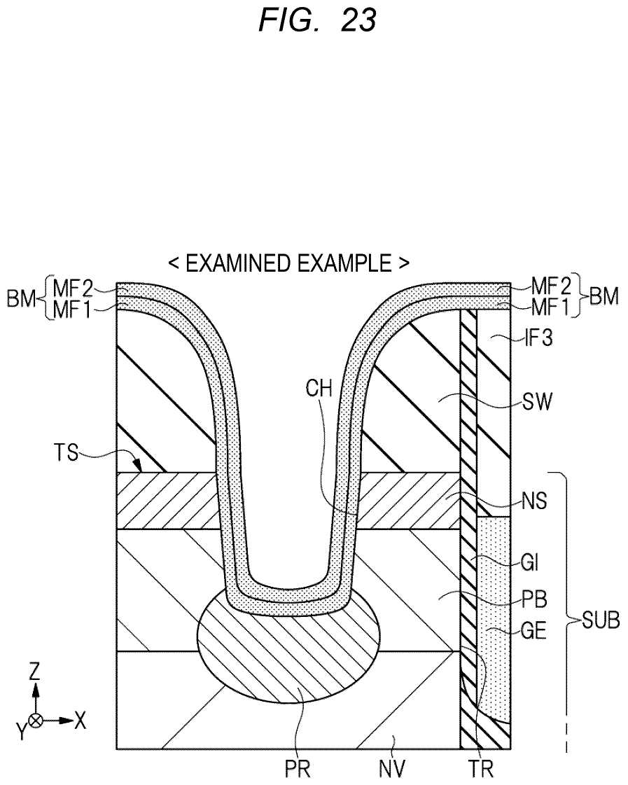

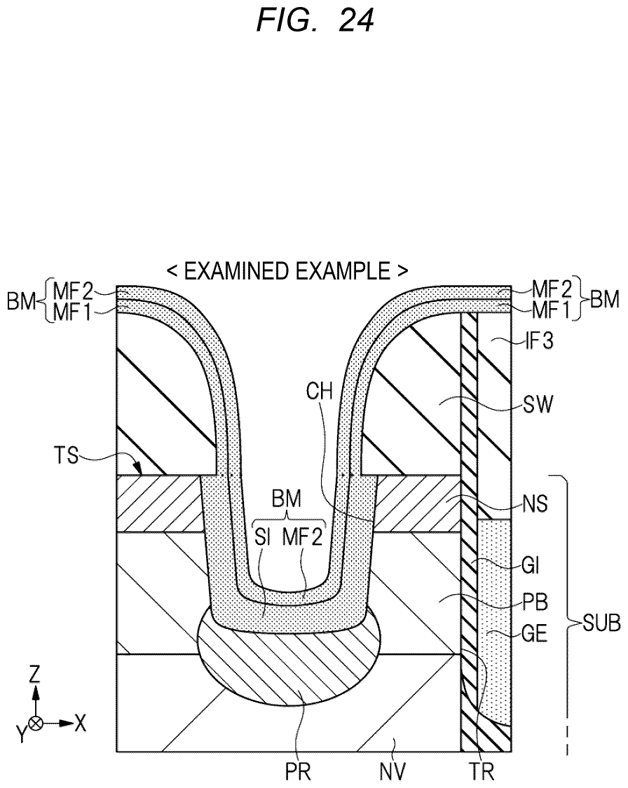

As shown in FIG. 23, for example, using a sputtering method or a CVD method, a metal film MF1 and a metal film MF2 are sequentially formed in the hole CH as the barrier metal film BM. The metal film MF1 is, for example, a titanium film. The metal film MF2 is, for example, a titanium nitride film. Next, as shown in FIG. 24, by performing heat treatment, the metal film MF1 is reacted with the silicon contained in the semiconductor substrate SUB to form a silicide film SI. The barrier metal film BM includes the silicide film SI and the metal film MF2.

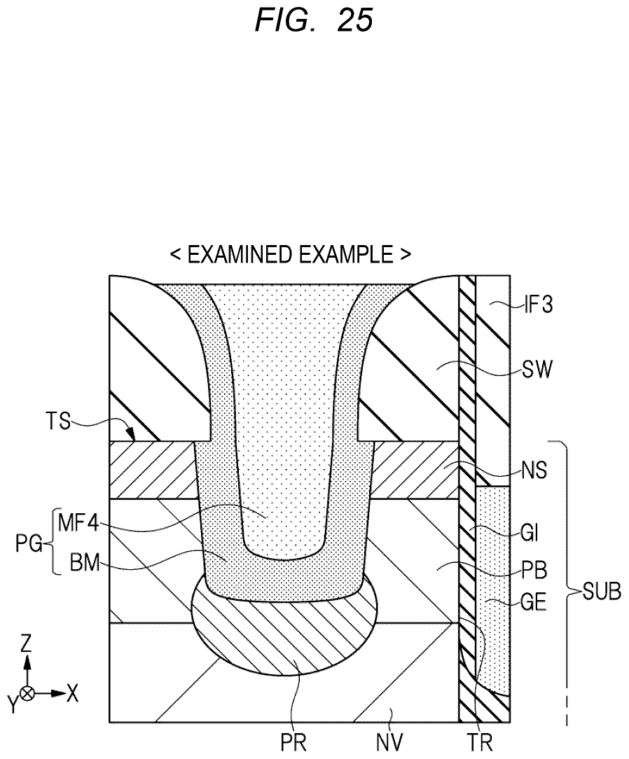

Next, as shown in FIG. 25, for example, using a CVD method, a metal film MF4 is formed in the hole CH via the barrier metal film BM. The metal film MF4 is, for example, a tungsten film. In this way, a plug PG including the barrier metal film BM and the metal film MF4 is formed in the hole CH.

As described above, with the recent trend of miniaturization of semiconductor devices 100, it is required to also reduce the opening width of the hole CH. Therefore, when forming the silicide film SI on the side portion CHs of the hole CH, there is a problem that the silicide film SI is easily formed near the channel region.

Additionally, when forming the silicide film SI, there may be cases where aggregation occurs in the silicide film SI, and cases where cracks occur in the metal film MF2 due to stress from the silicide film SI. When forming a tungsten film as the metal film MF4 using a CVD method, WF₆ gas is used. If cracks occur in the metal film MF2, defects such as “wormholes” or “volcanoes” are likely to occur due to the infiltration of WF₆ gas through the cracks.

Here, one of the purposes of forming the silicide film SI is to form ohmic contact with the body region PB and the contact region PR at the bottom portion CHb of the hole CH. Therefore, the formation conditions of the silicide film SI are optimized to prevent issues related to aggregation of the silicide film SI and cracks in the metal film MF2 at the bottom portion CHb of the hole CH.

For example, in the case of a titanium silicide film, if the thickness of the titanium film is too small, the temperature at which aggregation occurs becomes lower, and if the thickness of the titanium film is too large, unreacted titanium film is likely to remain. The unreacted titanium film may undergo silicide reaction again due to thermal load in subsequent manufacturing steps, applying stress to the metal film MF2 and causing cracks in the metal film MF2. Therefore, adjustments are made to the thickness of the metal film MF1 and the temperature of the heat treatment when forming the silicide film SI. This adjustment is made to suppress the above-mentioned problems that may occur at the bottom portion CHb of the hole CH, so it is difficult to suppress the above-mentioned problems at the side portion CHs of the hole CH.

In the first embodiment, while prioritizing the optimization of the formation conditions of the silicide film SI at the bottom portion CHb of the hole CH, the barrier metal film BM is formed relatively thinly or not formed at all on the side portion CHs of the hole CH. This suppresses the problems related to aggregation of the silicide film SI and cracks in the metal film MF2 on the side portion CHs of the hole CH.

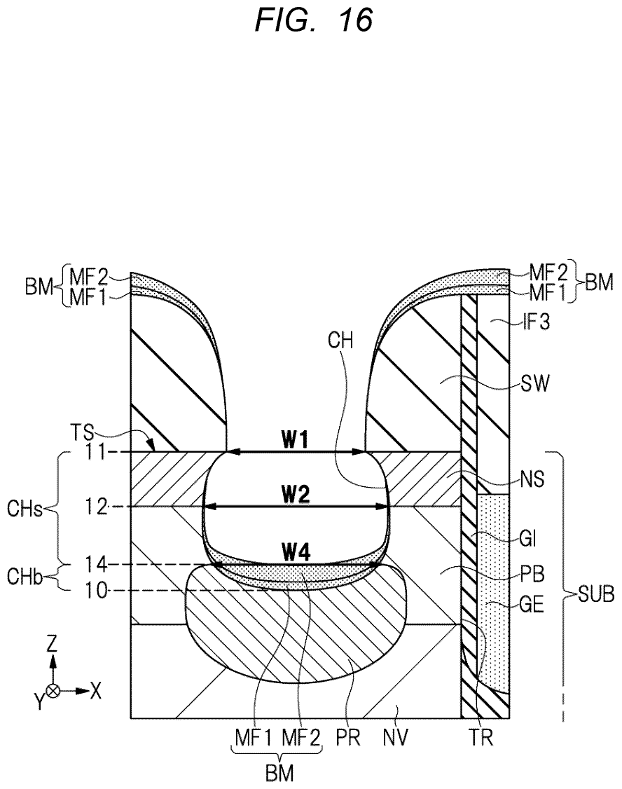

As shown in FIG. 16, the metal film MF1 and the metal film MF2 are formed as the barrier metal film BM in the hole CH, on the sidewall spacer SW, and on the insulating film IF3. First, for example, using a sputtering method, the metal film MF1 is formed in the hole CH, on the sidewall spacer SW, and on the insulating film IF3. Next, for example, using a sputtering method, the metal film MF2 is formed on the metal film MF1. The metal film MF1 is, for example, a titanium film. The metal film MF2 is, for example, a titanium nitride film.

The thickness of the metal film MF1 is, for example, 5 nm or more and 10 nm or less after film formation. The thickness of the metal film MF2 is greater than the thickness of the metal film MF1, for example, 10 nm or more and 20 nm or less after film formation. These values are measured over the deepest part 10 of the hole CH. Similarly, the thickness of the silicide film SI and the thickness of the metal film MF3 described later are also measured over the deepest part 10 of the hole CH.

As shown in FIG. 16, the fourth position 14 corresponds to the position of the upper surface of the barrier metal film BM formed over the deepest part 10 of the hole CH. The opening width W4 of the hole CH at the fourth position 14 is smaller than the opening width W2 and larger than the opening width W1.

In the following description, the portion of the hole CH extending from the first position 11 to the fourth position 14 is referred to as the side portion CHs of the hole CH, and the portion extending from the fourth position 14 to the deepest part 10 of the hole CH is referred to as the bottom portion CHb of the hole CH.

Here, the thickness of the barrier metal film BM formed in the hole CH and extending from the first position 11 to the fourth position 14 is smaller than the thickness of the barrier metal film BM formed in the hole CH and extending from the fourth position 14 to the deepest part 10. In other words, the thickness of the barrier metal film BM formed on the side portion CHs of the hole CH is smaller than the thickness of the barrier metal film BM formed on the bottom portion CHb of the hole CH. There are portions at the side portion CHs of the hole CH where the thickness of the barrier metal film BM is 0 nm. That is, there are portions at the side portion CHs of the hole CH where the barrier metal film BM is not formed.

Here, the “thickness of the barrier metal film BM” described here refers to the thickness in the direction perpendicular to the inner wall surface (side portion CHs, bottom portion CHb) of the hole CH. In the following description, there may be cases where the thicknesses of the barrier metal film BM, metal film MF1, metal film MF2, and metal film MF3 are compared. In such cases, their thicknesses are also in the direction perpendicular to the inner wall surface (side portion CHs, bottom portion CHb) of the hole CH.

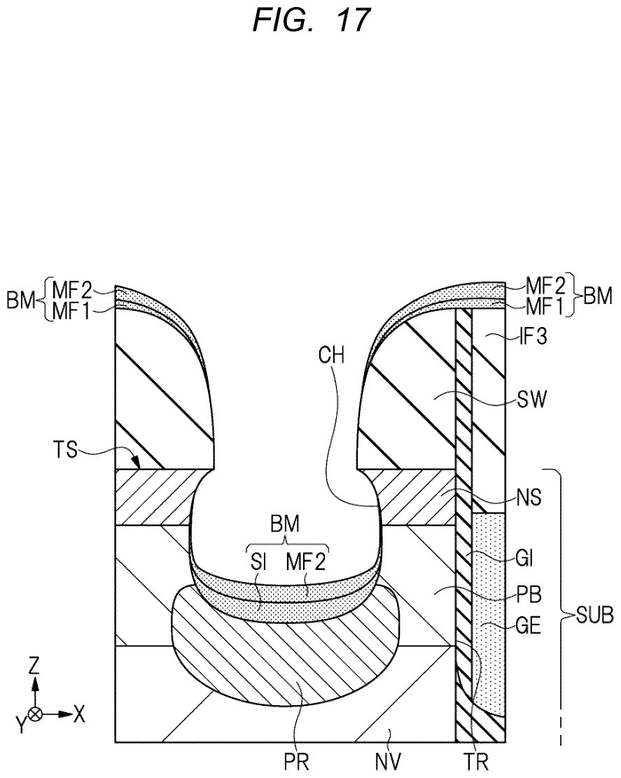

As shown in FIG. 17, by performing heat treatment, the metal film MF1 is reacted with the silicon contained in the semiconductor substrate SUB to form a silicide film SI. This heat treatment is performed, for example, in an inert gas atmosphere such as nitrogen, under conditions of, for example, 600 degrees Celsius or more and 700 degrees Celsius or less. The silicide film SI is, for example, a titanium silicide film. The thickness of the silicide film SI is, for example, 10 nm or more and 20 nm or less. The barrier metal film BM includes the silicide film SI formed in the hole CH and the metal film MF2 formed on the silicide film SI. The silicide film SI may also be formed on the side portion CHs of the hole CH and the metal film MF2, but there may also be cases where the silicide film SI and the metal film MF2 are not formed on the side portion CHs of the hole CH.

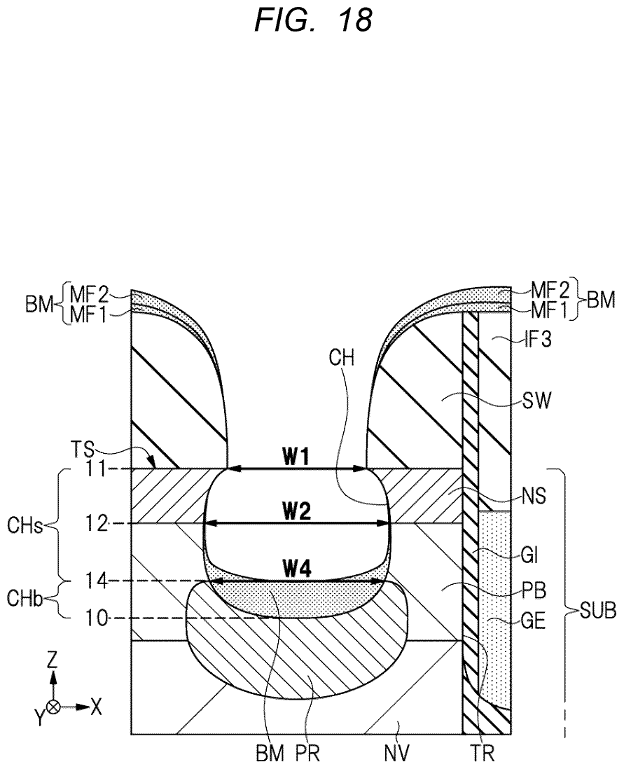

As shown in FIG. 18, even after forming silicide film SI, the opening width W4 of the hole CH at the fourth position 14 is smaller than the opening width W2 and larger than the opening width W1.

Furthermore, even after forming silicide film SI, the thickness of the barrier metal film BM formed in the hole CH from the first position 11 to the fourth position 14 is smaller than the thickness of the barrier metal film BM formed in the hole CH from the fourth position 14 to the deepest part 10. In other words, the thickness of the barrier metal film BM formed on the side portion CHs of the hole CH is smaller than the thickness of the barrier metal film BM formed on the bottom portion CHb of the hole CH. There may be portions at the side portion CHs of the hole CH where the thickness of the barrier metal film BM is 0 nm. That is, there may be portions at the side portion CHs of the hole CH where the barrier metal film BM is not formed.

Thus, in the first embodiment, the barrier metal film BM is relatively thickly formed on the bottom portion CHb of the hole CH to enable ohmic contact with the body region PB and the contact region PR. On the other hand, the barrier metal film BM is relatively thinly formed or not formed on the side portion CHs of the hole CH.

Therefore, it is possible to solve the problem that the silicide film SI is easily formed near the channel region. Additionally, it is possible to solve the problem of aggregation occurring in the silicide film SI and the problem of cracks occurring in the metal film MF2 due to stress from the silicide film SI. Consequently, the reliability of semiconductor device 100 can be improved.

Moreover, in the manufacturing step shown in FIG. 16, it is also possible to form the metal film MF1 and the metal film MF2 in the hole CH using the CVD method. However, in the case of the CVD method, the metal film MF1 and the metal film MF2 are also formed on the side portion CHs of the hole CH. Furthermore, the thickness of each of the metal film MF1 and the meal film MF2 formed on the side portion CHs of the hole CH becomes almost the same as the thickness of each of the metal film MF1 and the metal film MF2 formed on the bottom portion CHb of the hole CH. Therefore, it is preferable to form the metal film MF1 and the metal film MF2 using the sputtering method.

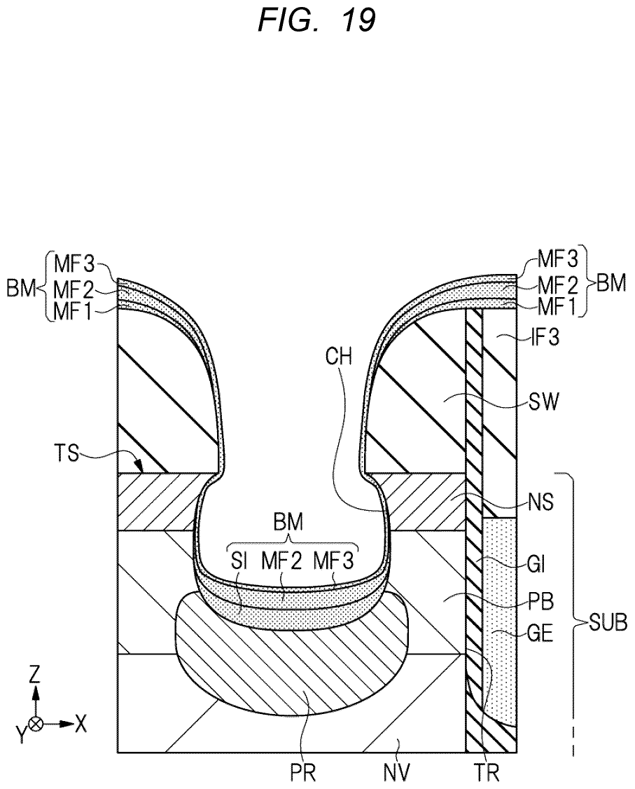

As shown in FIG. 19, it is preferable to form the metal film MF3 in the hole CH using the CVD method to cover the metal film MF2 and the silicide film SI. In this case, the barrier metal film BM includes not only the silicide film SI and the metal film MF2 but also the metal film MF3. The metal film MF3 is, for example, a titanium nitride film. The metal film MF3 is formed not only on the bottom portion CHb of the hole CH but also on the side portion CHs of the hole CH. Moreover, the thickness of the metal film MF3 formed on the side portion CHs of the hole CH becomes almost the same as the thickness of the metal film MF3 formed on the bottom portion CHb of the hole CH.

During the manufacturing step of the metal film MF4 described later, when forming a tungsten film as the metal film MF4 using the CVD method, WF₆ gas is used. In the first embodiment, there may be portions at the side portion CHs of the hole CH where the metal film MF2 and the silicide film SI are not formed, and the semiconductor substrate SUB may be directly exposed to the WF₆ gas. Therefore, to protect the portions where the metal film MF2 and the silicide film SI are not formed, the metal film MF3 is formed as part of the barrier metal film BM.

However, when forming the metal film MF3 using the CVD method, heat treatment of about 600 degrees Celsius is applied. This heat treatment may cause stress from the silicide film SI to be applied to the metal film MF2, which may cause cracks in the metal film MF2. Therefore, to minimize the deposition time of the metal film MF3, it is preferable that the thickness of the metal film MF3 is sufficient to protect the semiconductor substrate SUB from the WF₆ gas and is as small as possible. The thickness of the metal film MF3 is smaller than the thickness of the silicide film SI and the metal film MF2, for example, between 2 nm and 5 nm.

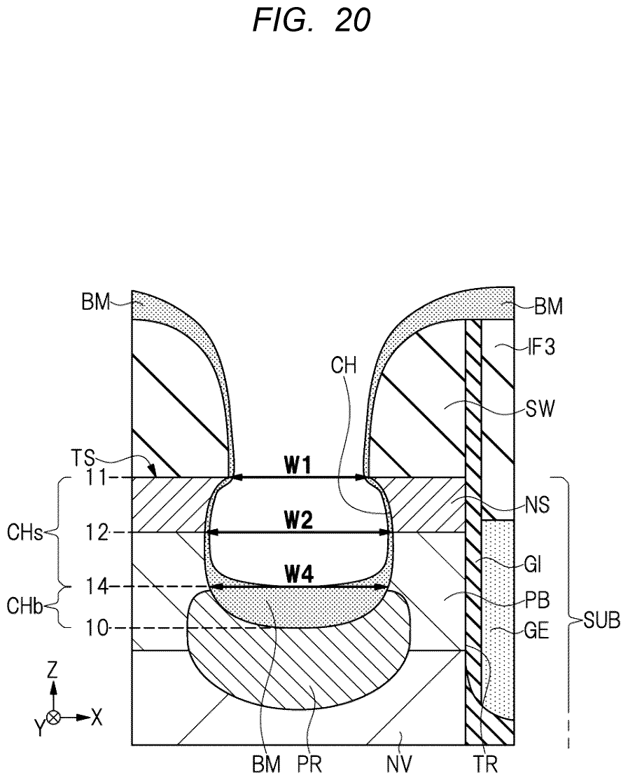

As shown in FIG. 20, when the metal film MF3 is formed, the fourth position 14 corresponds to the position of the upper surface of the barrier metal film BM (the upper surface of the metal film MF3) formed over the deepest part 10 of the hole CH.

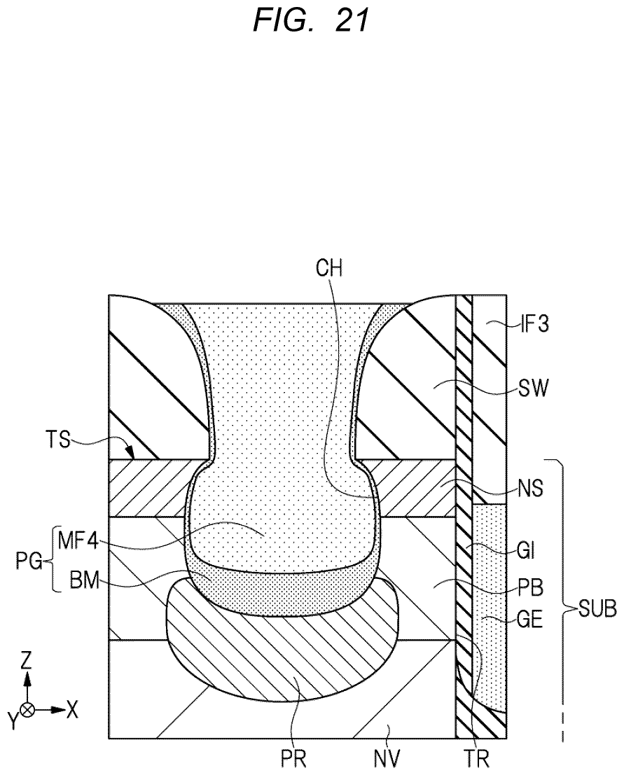

Thereafter, as shown in FIG. 21, a metal film MF4 is formed in the hole CH via the barrier metal film BM. As a result, a plug PG including the barrier metal film BM and the metal film MF4 is formed in the hole CH.

First, using the CVD method, the metal film MF4 is formed in the hole CH, on the sidewall spacer SW, and on the insulating film IF3. In this manufacturing step, WF₆ gas is used, and the metal film MF4 is a tungsten film. Next, by performing a polishing treatment using the CMP method or an anisotropic etching treatment, the metal film MF4 and the barrier metal film BM located on the sidewall spacer SW and on the insulating film IF3 are removed.

Although the present invention has been specifically described based on the above embodiment, the present invention is not limited to the above embodiment, and various modifications can be made without departing from the gist thereof.

For example, in the first embodiment, a titanium silicide film was exemplified and described as the silicide film SI, but similar issues may arise with other silicide films besides titanium silicide films. Therefore, the silicide film SI may be a silicide film other than a titanium silicide film.

What is claimed is:

1. A semiconductor device comprising:
a semiconductor substrate of a first conductivity type having an upper surface;
a trench formed in the semiconductor substrate to reach a predetermined depth from the upper surface of the semiconductor substrate;
a gate electrode formed in the trench;
an insulating film formed on the gate electrode to protrude from the upper surface of the semiconductor substrate;
a body region of a second conductivity type opposite to the first conductivity type formed in a portion of the semiconductor substrate exposed from the insulating film;
a source region of the first conductivity type formed in the body region;
a sidewall spacer formed on a side surface of the insulating film and on the upper surface of the semiconductor substrate;
a hole formed in a portion of the semiconductor substrate exposed from the insulating film and the sidewall spacer to penetrate through the source region and reach the body region; and
a barrier metal film formed in the hole,
wherein an opening width of the hole at a second position of a junction surface between the body region and the source region is larger than an opening width of the hole at a first position of the upper surface of the semiconductor substrate, and
wherein the barrier metal film comprises:
a silicide film formed in the hole; and
a second metal film formed on the silicide film.

2. The semiconductor device according to claim 1,
wherein an opening width of the hole at a fourth position of an upper surface of the barrier metal film formed over the deepest part of the hole is smaller than the opening width of the hole at the second position and larger than the opening width of the hole at the first position.

3. The semiconductor device according to claim 2,
wherein a thickness of the barrier metal film formed in the hole and extending from the first position to the fourth position is smaller than a thickness of the barrier metal film formed in the hole extending from the fourth position to the deepest part of the hole.

4. The semiconductor device according to claim 1,
wherein the barrier metal film comprises a third metal film formed in the hole to cover the second metal film and the silicide film, and
wherein a thickness of the third metal film is smaller than a thickness of the silicide film and a thickness of the second metal film.

5. The semiconductor device according to claim 4, comprising:
a tungsten film formed in the hole via the barrier metal film,
wherein the silicide film is a titanium silicide film,
wherein the second metal film is a titanium nitride film, and
wherein the third metal film is a titanium nitride film.

6. A method of manufacturing a semiconductor device, the method comprising:
(a) preparing a semiconductor substrate of a first conductivity type having an upper surface;
(b) after the (a), forming a trench in the semiconductor substrate so as to reach a predetermined depth from the upper surface of the semiconductor substrate;
(c) after the (b), forming a gate electrode in the trench;
(d) after the (c), forming an insulating film in the trench and on the gate electrode;
(e) after the (d), performing an etching treatment on the semiconductor substrate using the insulating film as a mask to lower a position of the upper surface of the semiconductor substrate below a position of an upper surface of the insulating film;
(f) after the (e), forming a body region of a second conductivity type opposite to the first conductivity type, in a portion of the semiconductor substrate exposed from the insulating film;
(g) after the (f), forming a source region of the first conductivity type in the body region;
(h) after the (g), forming a sidewall spacer on a side surface of the insulating film and on the upper surface of the semiconductor substrate;
(i) after the (h), performing an etching treatment on the semiconductor substrate using the insulating film and the sidewall spacer as a mask to form a hole, the hole penetrating through the source region and reaching the body region; and
(j) after the (i), forming a barrier metal film in the hole,
wherein before the (j), an opening width of the hole at a second position of a junction surface between the body region and the source region is larger than an opening width of the hole at a first position of the upper surface of the semiconductor substrate, and
wherein the (j) comprises:
(j1) forming a first metal film in the hole using a sputtering method;
(j2) after the (j1), forming a second metal film on the first metal film using a sputtering method; and
(j3) after the (j2), performing heat treatment to react the first metal film with silicon contained in the semiconductor substrate to form a silicide film.

7. The method according to claim 6,
wherein after the (j), the opening width of the hole at the second position is larger than the opening width of the hole at the first position.

8. The method according to claim 6,
wherein before the (j), an opening width of the hole at a third position 30 nm over the deepest part of the hole is smaller than the opening width of the hole at the second position and larger than the opening width of the hole at the first position.

9. The method according to claim 8,
wherein after the (j2) and before the (j3), a thickness of the barrier metal film formed in the hole and extending from the first position to the fourth position is smaller than a thickness of the barrier metal film formed in the hole and extending from the fourth position to the deepest part of the hole.

10. The method according to claim 6,
wherein after the (j), an opening width of the hole at a fourth position of an upper surface of the barrier metal film formed over the deepest part of the hole is smaller than the opening width of the hole at the second position and larger than the opening width of the hole at the first position.

11. The method according to claim 10,
wherein after the (j), a thickness of the barrier metal film formed in the hole and extending from the first position to the fourth position is smaller than a thickness of the barrier metal film formed in the hole and extending from the fourth position to the deepest part of the hole.

12. The method according to claim 6,
wherein the (j) comprises:
(j4) after the (j3), forming a third metal film in the hole using a CVD method to cover the second metal film and the silicide film,
wherein a thickness of the third metal film is smaller than a thickness of the silicide film and a thickness of the second metal film.

13. The method according to claim 12, comprising:
(k) after the (j), forming a tungsten film in the hole via the barrier metal film using a CVD method,
wherein the first metal film is a titanium film,
wherein the silicide film is a titanium silicide film,
wherein the second metal film is a titanium nitride film, and
wherein the third metal film is a titanium nitride film.

14. The method according to claim 6,
wherein the etching treatment in the (i) includes an anisotropic etching treatment using Cl₂ gas and O₂ gas, and
wherein a value of “a flow rate of the Cl₂ gas/a flow rate of the O₂ gas” is 6 or more and 13 or less.

15. The method according to claim 14,
wherein the flow rate of the Cl₂ gas is 60 sccm or more and 80 sccm or less, and
wherein the flow rate of the O₂ gas is 6 sccm or more and 10 sccm or less.

16. The method according to claim 14,
wherein the etching treatment in the (i) includes an isotropic etching treatment using buffered hydrofluoric acid.
